(19) United States
(12) Patent Application Publication
(10) Pub. No.: US 2026/0255588 A1
(43) Pub. Date: Aug. 27, 2026

(54) MEMORY DEVICE AND METHOD

(71) Applicant: Micron Technology, Inc., Boise, ID (US)

(72) Inventors: Vinay Nair, Boise, ID (US); Yen Ting Lin, Taichung City (TW); Sutharsan Ketharanathan, Boise, ID (US)

(21) Appl. No.: 19/548,609

(22) Filed: Feb. 24, 2026

Related U.S. Application Data
(60) Provisional application No. 63/763,466, filed on Feb. 26, 2025.

(51) Int. Cl. H10B 12/00

(52) U.S. Cl. CPC H10B 12/50; H10B 12/09; H10B 12/315

(57) ABSTRACT

Apparatus and methods are disclosed, including transistors, semiconductor devices and systems. Example semiconductor devices and methods include a number of contacts extending vertically from source/drain regions of the transistor in the memory devices in an array. Example semiconductor devices and methods further include a periphery region at an edge of the array and a number of dummy contacts in the periphery region. The dummy contact includes an electrically isolated metal plug.

### PRIORITY APPLICATION

This application claims the benefit of priority to U.S. Provisional Application Ser. No. 63/763,466, filed Feb. 26, 2025, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures and interconnect circuitry such as transistor contacts in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates selected components of a memory device in accordance with some example embodiments.

FIG. 3A illustrates a selected stage of manufacture of a memory device in accordance with some example embodiments.

FIG. 3B illustrates another selected stage of manufacture of a memory device in accordance with some example embodiments.

FIG. 3C illustrates another selected stage of manufacture of a memory device in accordance with some example embodiments.

FIG. 3D illustrates another selected stage of manufacture of a memory device in accordance with some example embodiments.

FIG. 3E illustrates another selected stage of manufacture of a memory device in accordance with some example embodiments.

FIG. 3F illustrates another selected stage of manufacture of a memory device in accordance with some example embodiments.

FIG. 4A illustrates another selected stage of manufacture of a memory device in accordance with some example embodiments.

FIG. 4B illustrates a semiconductor chip including a memory device in accordance with some example embodiments.

FIG. 5 illustrates an example method flow diagram in accordance with other example embodiments.

FIG. 6 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

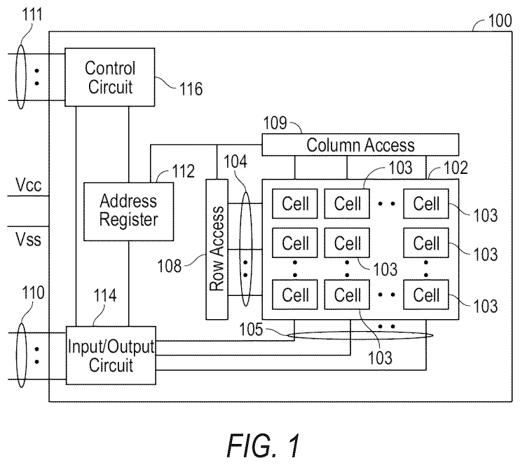

FIG. 1 shows a block diagram of an apparatus in the form of a memory device 100, according to an embodiment of the invention. Memory device 100 can include transistors with gate oxide configurations that have different thicknesses as described in more detail below. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

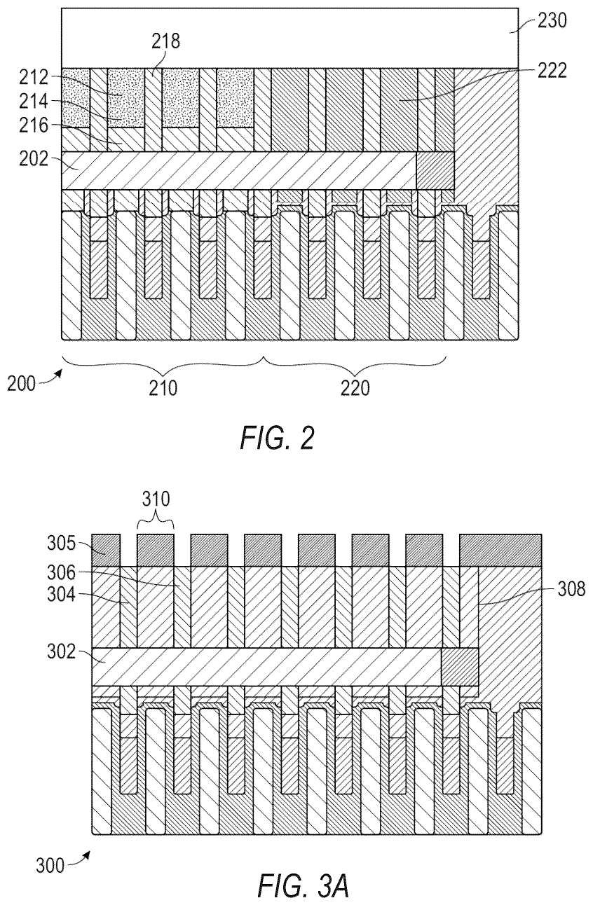

Memory cells 103 and other circuits 114, 116, etc. may include contacts and transistors and utilize methods as described in more detail in FIGS. 2-4. In one example, memory arrays 102 include NAND storage array, and peripheral circuits such as circuits 114, 116, 108, 109, etc. may include transistors as described in more detail in FIGS. 2-4. One example of a peripheral circuit that utilizes transistors as described includes a string driver circuit, although the invention is not so limited.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2 shows selected components of a semiconductor memory device according to one example. FIG. 2 includes a number of contacts 212 formed over an array 200 of memory devices on a semiconductor substrate. The number of contacts 212 are shown separated by contact isolation structures 218. In one example, the contact isolation structures 218 include dielectric material. In one example, the contact isolation structures 218 include a nitride. A digitline 202 is shown coupled to a number of transistors in the array 200. A number of contacts 212 are shown formed adjacent to the digitline 202. In the example of FIG. 2, the number of contacts 212 are configured to couple to source/drain regions of individual transistors in the array 200. To focus on the structures and methods of forming the number of contacts 212, additional details of the transistors are not shown. In one example, the array 200 includes a number of DRAM cells, although the invention is not so limited. Contact structures as described can be used with a number of other memory cell configurations in addition to DRAM cells.

In FIG. 2, the portion of the array 200 shown includes an active array region 210 and a periphery region 220. The periphery region 220 includes a number of contacts 212, however in the periphery region 220, the contacts 212 are dummy contacts 222. The dummy contacts 222 do not form any electrical connection to devices, and are included to simplify manufacture of the array 200. For example, the number of contacts 212 are formed all across a surface of the substrate. Then the edges of the array 200 are electrically isolated by forming dummy contacts 222 within the periphery region 220, while functioning electrical contacts 212 are connected to source/drain regions of active transistors within the active array region 210.

The active contacts 212 in FIG. 2 include a polysilicon portion 216 and a metal portion 214. The dummy contacts 222 in the example of FIG. 2 include a dielectric material to provide the desired electrical isolation at the periphery 220. In one example, the dielectric material includes an oxide, although the invention is not so limited. In one example, the dielectric material includes silicon oxide.

One or more layers of redistribution circuitry 230 is shown in block diagram format above the number of contacts 212 and the dummy contacts 222. One of ordinary skill in the art, having the benefit of the present disclosure, will recognize suitable components and manufacturing methods to form the redistribution circuitry 230.

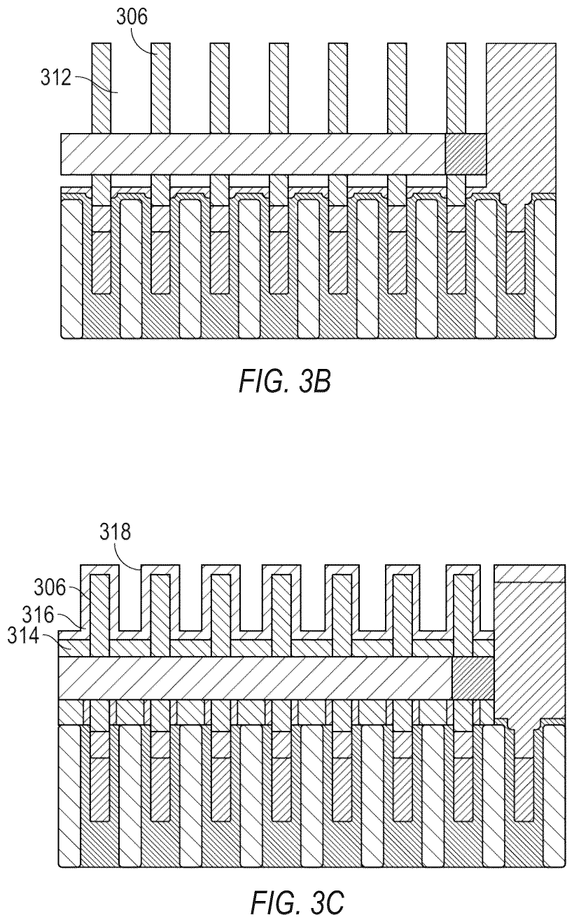

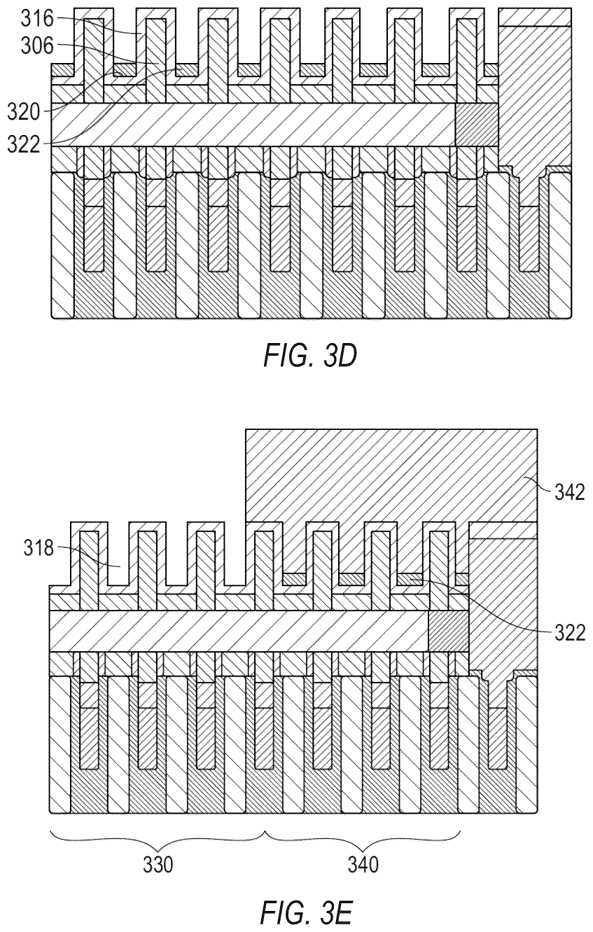

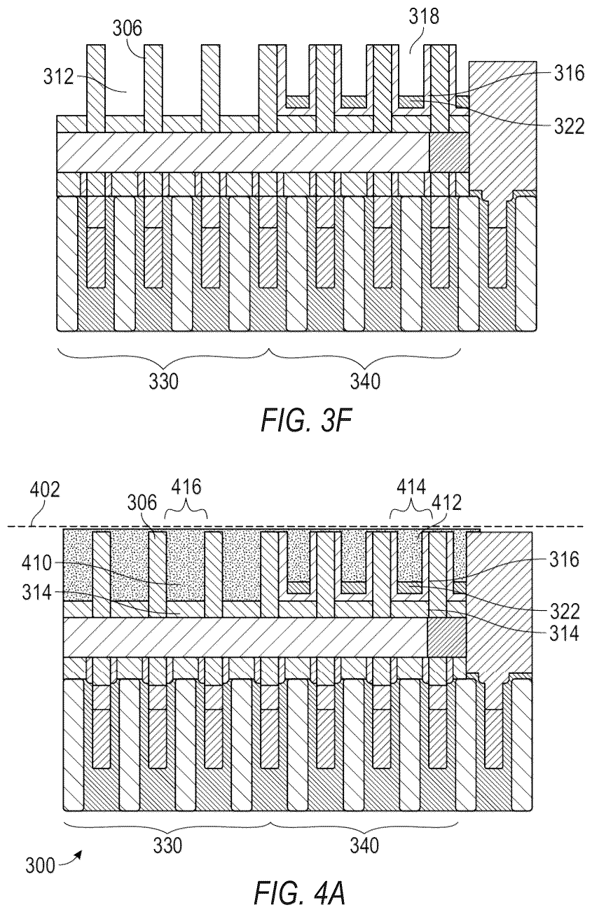

FIGS. 3A-3F show selected stages of manufacture of a semiconductor memory device similar to the semiconductor memory device shown in FIG. 2. In FIG. 3A, an array 300 of memory devices is shown, with a number of contact regions 310 separated by contact isolation structures 306. At the stage of manufacture shown in FIG. 3A, the contact regions 310 are filled with a placeholder material 304. In one example, the placeholder material includes carbon. A mask layer 305 is shown that is used to define the contact isolation structures 306 within the placeholder material 304. A lateral edge 308 of the array 300 is shown, with only a portion of the array 300 extending left in FIG. 3A from the lateral edge 308. A digitline 302 is shown, similar to digitline 202 from FIG. 2. The contact regions 310 of FIG. 3A are further processed in FIGS. 3B-3F to form a number of active contacts in a middle of the array 300, and a number of electrically isolated dummy contacts in a periphery of the array 300, adjacent to the lateral edge 308 of the array 300.

In FIG. 3B, the placeholder material 304 is removed from between the contact isolation structures 306 to form cavities 312. In FIG. 3C, the cavities 312 are filled with a conductive plug 314 in a bottom of the cavities 312. A liner layer 316 is formed on a base and sidewalls of the cavities 312, over the conductive plug 314. In one example, the conductive plug 314 includes polysilicon, although the invention is not so limited. Polysilicon includes an advantage of being acceptably conductive, and compatible with selective processing techniques described in more detail below. In one example, the liner layer 316 includes a dielectric. In one example, the liner layer 316 includes a nitride layer. In one example, the nitride layer includes silicon nitride, although the invention is not so limited. Similar to the conductive plug 314, choice of a nitride layer for the liner layer 316 provides advantages of being acceptably dielectric, and compatible with selective processing techniques described in more detail below. A second cavity 318, as a portion of the original cavity 312 remains in FIG. 3C, with the liner layer 316 on walls and a bottom of the second cavity 318, and the conductive plug 314 located beneath the liner layer 316 at a bottom of the cavity 312.

In FIG. 3D, a dielectric plug 322 is formed in a bottom of the second cavity 318, over the liner layer 316. In FIG. 3D, the dielectric plug 322 forms a direct interface 320 with the liner layer 316, with no intervening structures.

In FIG. 3E, a periphery mask 342 is formed over a periphery array portion 340, leaving an active array portion 330 exposed for further processing. In FIG. 3E, the dielectric plugs 322 are removed from a bottom portion of the second cavities 318 in the active array portion 330, while the periphery mask 342 keeps the dielectric plug 322 in place within the periphery array portion 340.

In FIG. 3F, the liner layer 316 has been removed from over the contact isolation structures 306 within the active array portion 330, opening up the cavities 312 from side to side between the contact isolation structures 306. In FIG. 3F, the periphery mask 342 is removed, exposing the dielectric plugs 322 in the periphery array portion 340. At this stage of manufacture, the second cavities 318 in the periphery array portion 340 include the dielectric plug 322.

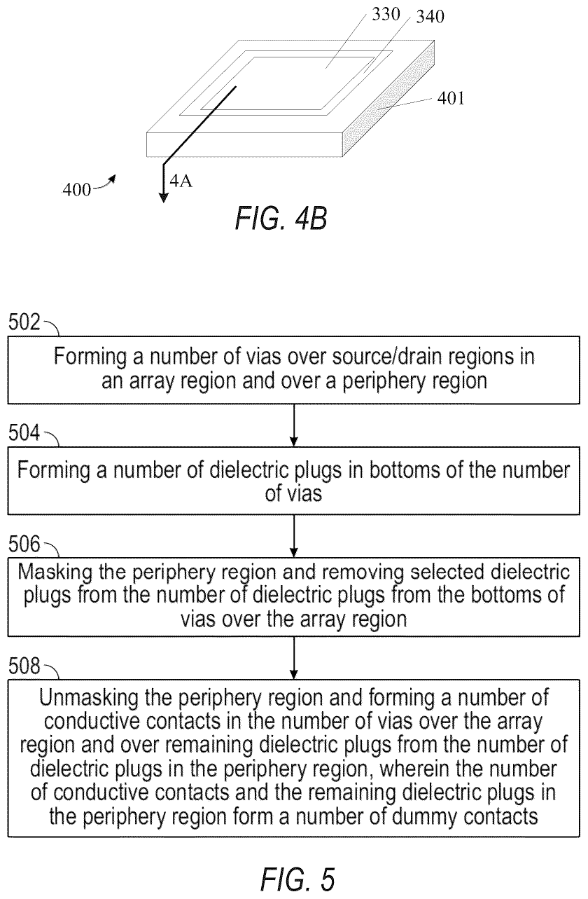

FIG. 4A shows a portion of a cross section along line 4A as indicated in FIG. 4B. FIG. 4B shows a view of a semiconductor die 400 that includes the array 300 to better show higher level context for FIG. 4A. The active array portion 330 is shown, with the periphery array portion 340 along edges of the active array portion 330. Elements of the array 330 are formed in a semiconductor substrate 401 of the semiconductor die 400.

In FIG. 4A, the second cavities 318 in the periphery array portion 340 and the cavities 312 in the active array portion 330 are both filled with a conductor. Dummy metal plugs 412 are shown in the periphery array portion 340, and active metal plugs 410 are shown in the active array portion 330. In one example, both the dummy metal plugs 412 and the active metal plugs 410 are formed from the same material in the same manufacturing operation. In one example, the conductor is metal. In one example, the metal includes tungsten.

Active array contacts 416 include the active metal plugs 410 and the conductive plug 314 in a bottom of the cavities 312. Dummy contacts 414 include the dummy metal plugs 412, dielectric plug 322, and the liner layer 316, all located over the conductive plug 314 within the periphery array portion 340. Because of the dielectric properties of the dielectric plug 322, and the liner layer 316, the dummy metal plugs 412 are electrically isolated from the conductive plug 314.

In FIG. 4A, a top surface of the array 300 is planarized, as indicated by dashed line 402. In this way, the dummy contacts 414 within the periphery array portion 340 and the active contacts 416 within the active array portion 330 are coplanar in FIG. 4A. Additionally, the dummy metal plugs 412 and a rim of the liner layer 316 in the number of dummy contacts 414 are coplanar as shown by line 402.

A concern in operation of memory devices includes electrical shorting between data lines at the level of conductive plug 314 and redistribution circuitry, such as redistribution circuitry 230 illustrated in FIG. 2. By making the dummy contacts 414 more robust, electrical shorting is reduced or eliminated at the periphery array portion 340. Additionally, a concern in manufacturing includes providing an effective etch stop across the array 300 before and during manufacture of the redistribution layer. Bu including the dummy metal plugs 412, and effective etch stop is provided. At the same, time, because the dummy metal plugs 412 are electrically isolated, there are no concerns about electrical shorting.

FIG. 5 shows a flow diagram of one example method of manufacture. In operation 502, a number of vias are formed over source/drain regions in an active array region and over a periphery array region. In operation 504, a number of dielectric plugs are formed in bottoms of the number of vias. In operation 506, the periphery array region is masked, and selected dielectric plugs are removed from the number of dielectric plugs from the bottoms of vias over the active array region. In operation 508, the periphery array region is unmasked, and a number of conductive contacts are formed in the number of vias over the active array region and over remaining dielectric plugs from the number of dielectric plugs in the periphery array region, wherein the number of conductive contacts and the remaining dielectric plugs in the periphery array region form a number of dummy contacts.

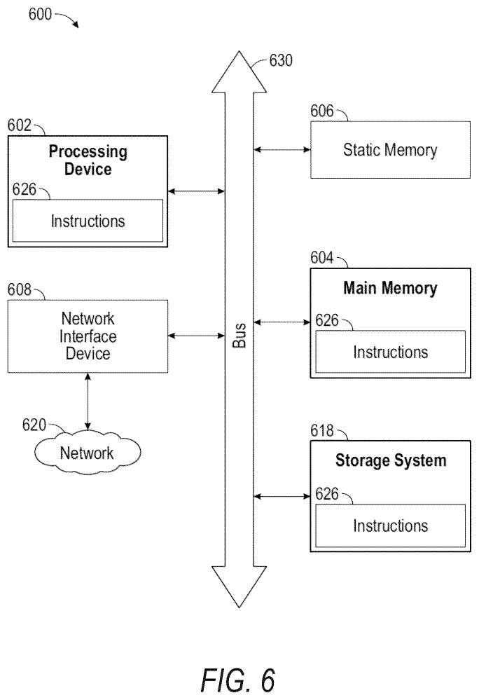

FIG. 6 illustrates a block diagram of an example machine (e.g., a host system) 900 which may include one or more electrical contacts, dummy contacts, transistors, memory devices and/or memory systems with gate dielectrics as described above. As discussed above, machine 600 may benefit from enhanced memory performance from use of one or more of the described transistor structures and/or memory systems, facilitating improved performance of machine 600 (as for many such machines or systems, efficient reading and writing of memory can facilitate improved performance of a processor or other components that machine, as described further below.

In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 600 may include a processing device 602 (e.g., a hardware processor, a central processing unit (CPU), a graphics processing unit (GPU), a hardware processor core, or any combination thereof, etc.), a main memory 604 (e.g., read-only memory (ROM), dynamic random-access memory (DRAM) such as synchronous DRAM (SDRAM) or Rambus DRAM (RDRAM), etc.), a static memory 606 (e.g., static random-access memory (SRAM), etc.), and a storage system 618, some or all of which may communicate with each other via a communication interface (e.g., a bus) 630. In one example, the main memory 604 includes one or more memory devices as described in examples above.

The processing device 602 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 can be configured to execute instructions 626 for performing the operations and steps discussed herein. The computer system 600 can further include a network interface device 608 to communicate over a network 620.

The storage system 618 can include a machine-readable storage medium (also known as a computer-readable medium) on which is stored one or more sets of instructions 626 or software embodying any one or more of the methodologies or functions described herein. The instructions 626 can also reside, completely or at least partially, within the main memory 604 or within the processing device 602 during execution thereof by the computer system 600, the main memory 604 and the processing device 602 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 600 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 600 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 626 (e.g., software, programs, an operating system (OS), etc.) or other data are stored on the storage system 618 can be accessed by the main memory 604 for use by the processing device 602. The main memory 604 (e.g., DRAM) is typically fast, but volatile, and thus a different type of storage than the storage system 618 (e.g., an SSD), which is suitable for long-term storage, including while in an “off” condition. The instructions 626 or data in use by a user or the machine 600 are typically loaded in the main memory 604 for use by the processing device 602. When the main memory 604 is full, virtual space from the storage system 618 can be allocated to supplement the main memory 604; however, because the storage system 618 device is typically slower than the main memory 604, and write speeds are typically at least twice as slow as read speeds, use of virtual memory can greatly reduce user experience due to storage system latency (in contrast to the main memory 604, e.g., DRAM). Further, use of the storage system 618 for virtual memory can greatly reduce the usable lifespan of the storage system 618.

The instructions 626 may further be transmitted or received over a network 620 using a transmission medium via the network interface device 608 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 608 may include one or more physical jacks (e.g., Ethernet, coaxial, or phone jacks) or one or more antennas to connect to the network 620. In an example, the network interface device 608 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Aspect 1. A semiconductor memory device, comprising: an array of memory devices formed on a semiconductor substrate, wherein memory devices in the array include a transistor; a number of contacts extending vertically from source/drain regions of the transistor in the memory devices in the array; a periphery region at an edge of the array of memory devices; a number of dummy contacts in the periphery region, wherein a dummy contact includes an electrically isolated metal plug.

Aspect 2. The semiconductor memory device of aspect 1, wherein the array of memory devices includes an array of DRAM cells.

Aspect 3. The semiconductor memory device of aspect 1, wherein the number of contacts include polysilicon and a metal.

Aspect 4. The semiconductor memory device of aspect 1, wherein the electrically isolated metal plug includes a same metal as a metal in the number of contacts.

Aspect 5. The semiconductor memory device of aspect 1, wherein the electrically isolated metal plug includes tungsten.

Aspect 6. The semiconductor memory device of aspect 1, wherein the number of dummy contacts are coplanar with a top surface of the number of contacts.

Aspect 7. A semiconductor memory device, comprising: an array of memory devices formed on a semiconductor substrate, wherein memory devices in the array include a transistor; a number of contacts extending vertically from source/drain regions in the memory devices in the array; a periphery region at an edge of the array of memory devices; a number of dummy contacts in the periphery region, wherein a dummy contact includes; a liner layer on a bottom portion and sidewalls of the dummy contact; a dielectric plug in the bottom portion of the dummy contact; and a metal plug in a top of the dummy contact.

Aspect 8. The semiconductor memory device of aspect 7, wherein the liner layer includes a conductive material.

Aspect 9. The semiconductor memory device of aspect 7, wherein the liner layer includes a nitride.

Aspect 10. The semiconductor memory device of aspect 7, wherein the dielectric plug includes an oxide.

Aspect 11. The semiconductor memory device of aspect 10, wherein the metal plug includes tungsten.

Aspect 12. The semiconductor memory device of aspect 7, wherein the number of contacts include polysilicon and a metal.

Aspect 13. The semiconductor memory device of aspect 7, wherein the number of dummy contacts are coplanar with a top surface of the number of contacts.

Aspect 14. The semiconductor memory device of aspect 13, wherein the metal plug and a rim of the liner layer in the number of dummy contacts are coplanar with a top surface of the number of contacts.

Aspect 15. A method, comprising: forming a number of vias over source/drain regions in an active array region and over a periphery array region; forming a number of dielectric plugs in bottoms of the number of vias; masking the periphery array region and removing selected dielectric plugs from the number of dielectric plugs from the bottoms of vias over the active array region; and unmasking the periphery array region and forming a number of conductive contacts in the number of vias over the active array region and over remaining dielectric plugs from the number of dielectric plugs in the periphery array region, wherein the number of conductive contacts and the remaining dielectric plugs in the periphery array region form a number of dummy contacts.

Aspect 16. The method of aspect 15, further including planarizing the active array region and the periphery array region.

Aspect 17. The method of aspect 15, further including forming a redistribution layer of conductive traces over the active array region.

Aspect 18. The method of aspect 15, further including forming a liner layer within the number of vias before forming the number of dielectric plugs in bottoms of the number of vias.

Aspect 19. The method of aspect 18, further including depositing polysilicon in bottoms of unmasked vias in the number of vias before forming the liner layer.

Aspect 20. The method of aspect 19, wherein masking the periphery array region and removing the selected dielectric plugs from the bottoms of vias over the active array region further includes removing the liner layer from the bottoms of vias over the active array region.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor memory device, comprising:
an array of memory devices formed on a semiconductor substrate, wherein memory devices in the array include a transistor;
a number of contacts extending vertically from source/drain regions of the transistor in the memory devices in the array;
a periphery region at an edge of the array of memory devices;
a number of dummy contacts in the periphery region, wherein a dummy contact includes an electrically isolated metal plug.

2. The semiconductor memory device of claim 1, wherein the array of memory devices includes an array of DRAM cells.

3. The semiconductor memory device of claim 1, wherein the number of contacts include polysilicon and a metal.

4. The semiconductor memory device of claim 1, wherein the electrically isolated metal plug includes a same metal as a metal in the number of contacts.

5. The semiconductor memory device of claim 1, wherein the electrically isolated metal plug includes tungsten.

6. The semiconductor memory device of claim 1, wherein the number of dummy contacts are coplanar with a top surface of the number of contacts.

7. A semiconductor memory device, comprising:
an array of memory devices formed on a semiconductor substrate, wherein memory devices in the array include a transistor;
a number of contacts extending vertically from source/drain regions in the memory devices in the array;
a periphery region at an edge of the array of memory devices;
a number of dummy contacts in the periphery region, wherein a dummy contact includes;
a liner layer on a bottom portion and sidewalls of the dummy contact;
a dielectric plug in the bottom portion of the dummy contact; and
a metal plug in a top of the dummy contact.

8. The semiconductor memory device of claim 7, wherein the liner layer includes a conductive material.

9. The semiconductor memory device of claim 7, wherein the liner layer includes a nitride.

10. The semiconductor memory device of claim 7, wherein the dielectric plug includes an oxide.

11. The semiconductor memory device of claim 10, wherein the metal plug includes tungsten.

12. The semiconductor memory device of claim 7, wherein the number of contacts include polysilicon and a metal.

13. The semiconductor memory device of claim 7, wherein the number of dummy contacts are coplanar with a top surface of the number of contacts.

14. The semiconductor memory device of claim 13, wherein the metal plug and a rim of the liner layer in the number of dummy contacts are coplanar with a top surface of the number of contacts.

15. A method, comprising:
forming a number of vias over source/drain regions in an active array region and over a periphery array region;
forming a number of dielectric plugs in bottoms of the number of vias;
masking the periphery array region and removing selected dielectric plugs from the number of dielectric plugs from the bottoms of vias over the active array region; and
unmasking the periphery array region and forming a number of conductive contacts in the number of vias over the active array region and over remaining dielectric plugs from the number of dielectric plugs in the periphery array region, wherein the number of conductive contacts and the remaining dielectric plugs in the periphery array region form a number of dummy contacts.

16. The method of claim 15, further including planarizing the active array region and the periphery array region.

17. The method of claim 15, further including forming a redistribution layer of conductive traces over the active array region.

18. The method of claim 15, further including forming a liner layer within the number of vias before forming the number of dielectric plugs in bottoms of the number of vias.

19. The method of claim 18, further including depositing polysilicon in bottoms of unmasked vias in the number of vias before forming the liner layer.

20. The method of claim 19, wherein masking the periphery array region and removing the selected dielectric plugs from the bottoms of vias over the active array region further includes removing the liner layer from the bottoms of vias over the active array region.
